(19) United States
(12) Patent Application Publication
(10) Pub. No.: US 2020/0058467 A1
(43) Pub. Date: Feb. 20, 2020

(54) PLASMA PROCESSING APPARATUS

(71) Applicant: TOKYO ELECTRON LIMITED, Tokyo (JP)

(72) Inventors: Yohei YAMAZAWA, Yamanashi (JP); Kazuki DENPOH, Yamanashi (JP); Jun YAMAWAKU, Yamanashi (JP)

(73) Assignee: TOKYO ELECTRON LIMITED, Tokyo (JP)

(21) Appl. No.: 16/662,715

(22) Filed: Oct. 24, 2019

Related U.S. Application Data
(62) Division of application No. 14/991,383, filed on Jan. 8, 2016, now abandoned.
Application No. 14/991,383 is a division of application No. 12/913,209, filed on Oct. 27, 2010, now abandoned.
(60) Provisional application No. 61/265,551, filed on Dec. 1, 2009.

(30) Foreign Application Priority Data
Oct. 27, 2009 (JP) 2009-246014

(51) Int. Cl. H01J 37/32; C23C 16/505

(52) U.S. Cl. CPC H01J 37/3211; H01J 37/321; C23C 16/505; H01J 37/3244

(57) ABSTRACT

A plasma processing apparatus includes a processing chamber, a part of which is formed of a dielectric window; a substrate supporting unit, provided in the processing chamber, for mounting a target substrate; a processing gas supply unit for supplying a processing gas to the processing chamber to perform a plasma process on the target substrate; an RF antenna, provided outside the dielectric window, for generating a plasma from the processing gas by an inductive coupling in the processing chamber; and an RF power supply unit for supplying an RF power to the RF antenna. The RF antenna includes a single-wound or multi-wound coil conductor having a cutout portion in a coil circling direction; and a pair of RF power lines from the RF power supply unit are respectively connected to a pair of coil end portions of the coil conductor that are opposite to each other via the cutout portion.

### CROSS-REFERENCE TO RELATED APPLICATIONS

This application is a division of application Ser. No. 14/991,383, filed Jan. 8, 2016, which is a division of application Ser. No. 12/913,209, filed Oct. 27, 2010, and also claims the benefit of priority to Japanese Patent Application No. 2009-246014, filed Oct. 27, 2009 and U.S. Provisional Application No. 61/265,551, filed Dec. 1, 2009, the entire contents of which are incorporated herein by reference.

### FIELD OF THE INVENTION

The present invention relates to a technique for performing a plasma process on a target substrate to be processed; and, more particularly, to an inductively coupled plasma processing apparatus.

### BACKGROUND OF THE INVENTION

In the manufacturing process of a semiconductor device or a flat panel display (FPD), a plasma is widely used in a process such as etching, deposit, oxidation, sputtering or the like since it has a good reactivity with a processing gas at a relatively low temperature. In such plasma process, the plasma is mostly generated by a radio frequency (RF) discharge in the megahertz range. Specifically, the plasma generated by the RF discharge is classified into a capacitively coupled plasma and an inductively coupled plasma.

Typically, an inductively coupled plasma processing apparatus includes a processing chamber, at least a portion (e.g., a ceiling portion) of which is formed of a dielectric window; and a coil-shaped RF antenna provided outside the dielectric window, and an RF power is supplied to the RF antenna. The processing chamber serves as a vacuum chamber capable of being depressurized, and a target substrate (e.g., a semiconductor wafer, a glass substrate or the like) to be processed is provided at a central portion of the chamber. Further, a processing gas is introduced into a processing space between the dielectric window and the substrate.

As an RF current flows though the RF antenna, an RF magnetic field is generated around the RF antenna, wherein the magnetic force lines of the RF magnetic field travels through the dielectric window and the processing space. The temporal alteration of the generated RF magnetic field causes an electric field to be induced azimuthally. Moreover, electrons azimuthally accelerated by the induced electric field collide with molecules and/or atoms of the processing gas, to thereby ionize the processing gas and generate a plasma in a doughnut shape.

By increasing the size of the processing space in the chamber, the plasma is efficiently diffused in all directions (especially, in the radical direction), thereby making the density of the plasma on the substrate uniform. Since, however, the RF antenna formed of a typical concentric or spiral coil includes an RF input-output terminal connected through an RF power supply line to an RF power supply in a loop thereof, it is inevitable to employ a nonaxissymmetric antenna configuration. This serves as a main factor that makes the plasma density nonuniform in the azimuthal direction. Accordingly, according to the conventional method, by using two-layered series-connected coils as the RF antenna and hiding RF power supply wire-connected locations (input-output terminals) provided in the upper coil behind the lower coil, the locations may not be electromagnetically seen from the plasma (see, e.g., Japanese Patent Applications Publication Nos. 2003-517197 and 2004-537830).

However, such conventional method of using the two-layered series-connected coils as the RF antenna is disadvantageous in that it is difficult to manufacture the RF antenna due to its complex configuration; or, by the extended length of the coils, the impedance is increased and the wavelength effect is caused.

### SUMMARY OF THE INVENTION

In view of the above, the present invention provides an inductively coupled plasma processing apparatus, capable of improving the uniformity in the azimuthal direction of a plasma density distribution by allowing locations on a current loop of an RF input-output terminal of its RF antenna not to be seen while substantially maintaining the length of coils of the RF antenna.

In accordance with a first aspect of the present invention, there is provided a plasma processing apparatus including a processing chamber, at least a part of which is formed of a dielectric window; a substrate supporting unit, provided in the processing chamber, for mounting thereon a target substrate to be processed; a processing gas supply unit for supplying a desired processing gas to the processing chamber to perform a desired plasma process on the target substrate; an RF antenna, provided outside the dielectric window, for generating a plasma from the processing gas by an inductive coupling in the processing chamber; and an RF power supply unit for supplying an RF power to the RF antenna, the RF power having an appropriate frequency for RF discharge of the processing gas. The RF antenna includes a single-wound or multi-wound coil conductor having a cutout portion in a coil circling direction, the cutout portion having a predetermined gap width; and a pair of RF power lines from the RF power supply unit are respectively connected to a pair of coil end portions of the coil conductor that are opposite to each other via the cutout portion.

In the inductively coupled plasma processing apparatus, when the RF power is supplied from the RF supply unit to the RF antenna, an RF magnetic field is generated around the antenna conductor by the RF current flowing though the RF antenna and, thus, an electric field contributing to the RF discharge of the processing gas is induced in the processing chamber. Accordingly, electrons azimuthally accelerated by the induced electric field collide with molecules and/or atoms in the etching gas, to thereby ionize the etching gas and generate a plasma in a doughnut shape. In the wide processing space, radicals and ions of the plasma generated in the doughnut shape are diffused in all directions, so that the radicals isotropically pour down and the ions are attracted by the DC bias onto a top surface (target surface) of the target substrate mounted on substrate supporting unit. The uniformity of the process on the substrate depends on that of the plasma density on the substrate.

In the plasma processing apparatus of the first aspect, with the above configuration, especially, where the RF antenna includes the single-wound or multi-wound coil conductor (having the cutout portion whose gap width of preferably about 10 mm or less in the coil circling direction and the distance having about 10 mm or less between the RF power supply points); and the pair of RF antenna power supply lines from the RF power supply unit are respectively connected to the pair of coil end portions that are opposite to each other via the cutout portion of the coil conductor, RF power supply wire-connected locations (input-output terminals) are not seen at singularities on the current loop from the plasma side and, thus, it is possible to improve the uniformity of the plasma density distribution in the azimuthal direction.

In accordance with a second aspect of the present invention, there is provided a plasma processing apparatus including a processing chamber, at least a part of which is formed of a dielectric window; a substrate supporting unit, provided in the processing chamber, for mounting thereon a target substrate to be processed; a processing gas supply unit for supplying a desired processing gas to the processing chamber to perform a desired plasma process on the target substrate; an RF antenna, provided outside the dielectric window, for generating a plasma from the processing gas by an inductive coupling in the processing chamber; and an RF power supply unit for supplying an RF power to the RF antenna, the RF power having an appropriate frequency for RF discharge of the processing gas. The RF antenna includes a first and a second coil conductor extended in parallel to be adjacent with each other, a cutout portion being provided at a same location in a coil circling direction in each of the respective coil conductors; a first connection conductor commonly connected to one coil end portions of the coil conductors adjacent to the cutout portions of the coil conductors; a second connection conductor commonly connected to the other coil end portions of the coil conductors adjacent to the cutout portions of the coil conductors; a third connection conductor extended from the first connection conductor into the cutout portion thereof and connected to a first RF power supply line from the RF power supply; and a fourth connection conductor extended from the second connection conductor into the cutout portion thereof and connected to a second RF power supply line from the RF power supply unit.

In the plasma processing apparatus of the second aspect, with the above configuration, especially, where the RF antenna includes the first and the second coil conductor extended in parallel to be adjacent with each other, the cutout portion being provided at the same location in the coil circling direction in each of the respective coil conductors; the first connection conductor commonly connected to one coil end portions of the coil conductors adjacent to the cutout portions of the coil conductors; the second connection conductor commonly connected to the other coil end portions of the coil conductors adjacent to the cutout portions of the coil conductors; the third connection conductor extended from the first connection conductor into the cutout portion thereof and connected to the first RF power supply line from the RF power supply; and the fourth connection conductor extended from the second connection conductor into the cutout portion thereof and connected to the second RF power supply line from the RF power supply unit, RF power supply wire-connected locations (input-output terminals) are not seen at singularities on the current loop from the plasma side and, thus, it is possible to improve the uniformity of the plasma density distribution in the azimuthal direction.

In accordance with a third aspect of the present invention, there is provided a plasma processing apparatus including a processing chamber, at least a part of which is formed of a dielectric window; a substrate supporting unit, provided in the processing chamber, for mounting thereon a target substrate to be processed; a processing gas supply unit for supplying a desired processing gas to the processing chamber to perform a desired plasma process on the target substrate; an RF antenna, provided outside the dielectric window, for generating a plasma from the processing gas by an inductive coupling in the processing chamber; and an RF power supply unit for supplying an RF power to the RF antenna, the RF power having an appropriate frequency for RF discharge of the processing gas. The RF antenna includes a single-wound or multi-wound coil conductor having a plurality of cutout portions that are arranged at a regular interval in a coil circling direction, and a pair of RF power supply lines from the RF power supply unit are respectively connected to a pair of coil end portions of the coil conductor that are opposite to each other via one of the cutout portions. Moreover, a bridge-type connection conductor is provided at each of the other cutout portions to connect a pair of coil end portions thereof that are opposite to each other via the corresponding cutout portion.

In the plasma processing apparatus of the third aspect, with the above configuration, especially, where the RF antenna includes the single-wound or multi-wound coil conductor having the plural cutout portions that are arranged at the regular interval in a coil circling direction; a pair of RF power supply lines from the RF power supply unit are respectively connected to a pair of coil end portions of the coil conductor that are opposite to each other via one of the cutout portions; and the bridge-type connection conductor is provided at each of the other cutout portions to connect the pair of coil end portions thereof that are opposite to each other via the corresponding cutout portion, RF power supply wire-connected locations (input-output terminals) are not seen at singularities on the current loop from the plasma side and, thus, it is possible to improve the uniformity of the plasma density distribution in the azimuthal direction.

In accordance with a fourth aspect of the present invention, there is provided a plasma processing apparatus including a processing chamber, at least a part of which is formed of a dielectric window; a substrate supporting unit, provided in the processing chamber, for mounting thereon a target substrate to be processed; a processing gas supply unit for supplying a desired processing gas to the processing chamber to perform a desired plasma process on the target substrate; an RF antenna, provided outside the dielectric window, for generating a plasma from the processing gas by an inductive coupling in the processing chamber; and an RF power supply unit for supplying an RF power to the RF antenna, the RF power having an appropriate frequency for RF discharge of the processing gas. The RF antenna includes a single-wound or multi-wound coil conductor having a cutout portion in a coil circling direction; and a pair of connection conductors respectively obliquely extended at a predetermined angle with regard to a coil circling direction from a pair of coil end portions that are opposite to each other via the cutout portion of the coil conductor in an opposite direction to the dielectric window, and a pair of RF power supply lines from the RF power supply unit are respectively connected to the connection conductors.

In the plasma processing apparatus of the fourth aspect, with the above configuration, especially, where RF antenna includes the single-wound or multi-wound coil conductor having a cutout portion in the coil circling direction; the pair of connection conductors respectively obliquely extended at a predetermined angle with regard to a coil circling direction from the pair of coil end portions that are opposite to each other via the cutout portion of the coil conductor in the opposite direction to the dielectric window; and the pair of RF power supply lines from the RF power supply unit are respectively connected to the connection conductors, RF power supply wire-connected locations (input-output terminals) are not seen at singularities on the current loop from the plasma side and, thus, it is possible to improve the uniformity of the plasma density distribution in the azimuthal direction.

In accordance with a fifth aspect of the present invention, there is provided a plasma processing apparatus including a processing chamber, at least a part of which is formed of a dielectric window; a substrate supporting unit, provided in the processing chamber, for mounting thereon a target substrate to be processed; a processing gas supply unit for supplying a desired processing gas to the processing chamber to perform a desired plasma process on the target substrate; an RF antenna, provided on the dielectric window, for generating a plasma from the processing gas by an inductive coupling in the processing chamber; and an RF power supply unit for supplying an RF power to the RF antenna, the RF power having an appropriate frequency for RF discharge of the processing gas. The RF antenna includes a main coil conductor vortically extended with regard to a planar surface; and a sub coil conductor vortically extended with regard to the planar surface from a peripheral coil end portion of the main coil conductor upwardly at a predetermined inclined angle, one of a pair of RF power lines from the RF power supply unit is connected to a central coil end portion of the main coil conductor, and the other RF power line from the RF power supply unit is connected to an upper coil end portion of the sub coil conductor.

In the plasma processing apparatus of the fifth aspect, with the above configuration, especially, where the RF antenna includes the main coil conductor vortically extended with regard to a planar surface; and the sub coil conductor vortically extended with regard to the planar surface from the peripheral coil end portion of the main coil conductor upwardly at a predetermined inclined angle; one of the pair of RF power lines from the RF power supply unit is connected to the central coil end portion of the main coil conductor; and the other RF power line from the RF power supply unit is connected to an upper coil end portion of the sub coil conductor, RF power supply wire-connected locations (input-output terminals) are not seen at singularities on the current loop from the plasma side and, thus, it is possible to improve the uniformity of the plasma density distribution in the azimuthal direction.

### BRIEF DESCRIPTION OF THE DRAWINGS

The objects and features of the present invention will become apparent from the following description of embodiments, given in conjunction with the accompanying drawings, in which:

FIG. 1 is a longitudinal cross sectional view showing a configuration of an inductively coupled plasma etching apparatus in accordance with an embodiment of the present invention;

FIG. 2 is a plan view showing a basic structure of a coil of an RF antenna in a first test example;

FIG. 3 is a contour plot diagram showing distribution characteristics in an azimuthal direction of the current density in a plasma generated in a doughnut shape in an electromagnetic field simulation for the first test example shown in FIG. 2;

FIG. 4 is a plan view for explaining an example of variously adjusting a distance between RF power supply points in a second test example;

FIG. 5 is a contour plot diagram showing distribution characteristics in an azimuthal direction of the current density in a plasma generated in a doughnut shape in an electromagnetic field simulation for the second test example shown in FIG. 4;

FIG. 6 is a plan view showing a structure of a coil of an RF antenna in a third test example;

FIG. 7 is a contour plot diagram showing distribution characteristics in an azimuthal direction of the current density in a plasma generated in a doughnut shape in an electromagnetic field simulation for the third test example shown in FIG. 6;

FIG. 8A is a plan view showing a structure of a coil of an RF antenna in a fourth test example;

FIG. 8B shows a cross section of the RF antenna;

FIG. 9 is a plan view showing a structure of a coil of an RF antenna in a fifth test example;

FIG. 10 is a contour plot diagram showing distribution characteristics in an azimuthal direction of the current density in a plasma generated in a doughnut shape in an electromagnetic field simulation for the fifth test example shown in FIG. 9;

FIG. 11 is a plan view showing a structure of a coil of an RF antenna in a modification of the fifth test example shown in FIG. 9;

FIG. 12 is a plan view showing a structure of a coil of an RF antenna in another modification of the fifth test example shown in FIG. 9;

FIG. 13 is a perspective view showing a structure of a coil of an RF antenna in a sixth test example;

FIG. 14 is a perspective view showing a structure of a coil of an RF antenna in a seventh test example;

FIG. 15 is a perspective view showing a structure of a coil of an RF antenna in an eighth test example;

FIG. 16A is a perspective view showing a coil structure of an RF antenna in a test example;

FIG. 16B is a perspective view showing the coil structure of the RF antenna shown in FIG. 16A, from another angle (direction);

FIG. 17A is a contour plot diagram showing distribution characteristics in an azimuthal direction (r=80, 120 and 170 mm) of the current density in a plasma generated in a doughnut shape in an electromagnetic field simulation for the test example shown in FIGS. 16A and 16B;

FIG. 17B is a contour plot diagram showing distribution characteristics in an azimuthal direction (r=230 mm) of the current density in a plasma generated in a doughnut shape in an electromagnetic field simulation for the test example shown in FIGS. 16A and 16B;

FIG. 18 is a perspective view showing a structure of a coil of an RF antenna in a comparison example;

FIG. 19A is a contour plot diagram showing distribution characteristics in an azimuthal direction (r=80, 120 and 170 mm) of the current density in a plasma generated in a doughnut shape in an electromagnetic field simulation for the comparison example shown in FIG. 18;

FIG. 19B is a contour plot diagram showing distribution characteristics in an azimuthal direction (r=230 mm) of the current density in a plasma generated in a doughnut shape in an electromagnetic field simulation for the comparison example shown in FIG. 18; and

FIGS. 20A to 20D show a structure of a coil of an RF antenna in a ninth test example.

### DETAILED DESCRIPTION OF THE EMBODIMENTS

An embodiment of the present invention will now be described with reference to the accompanying drawings which form a part hereof.

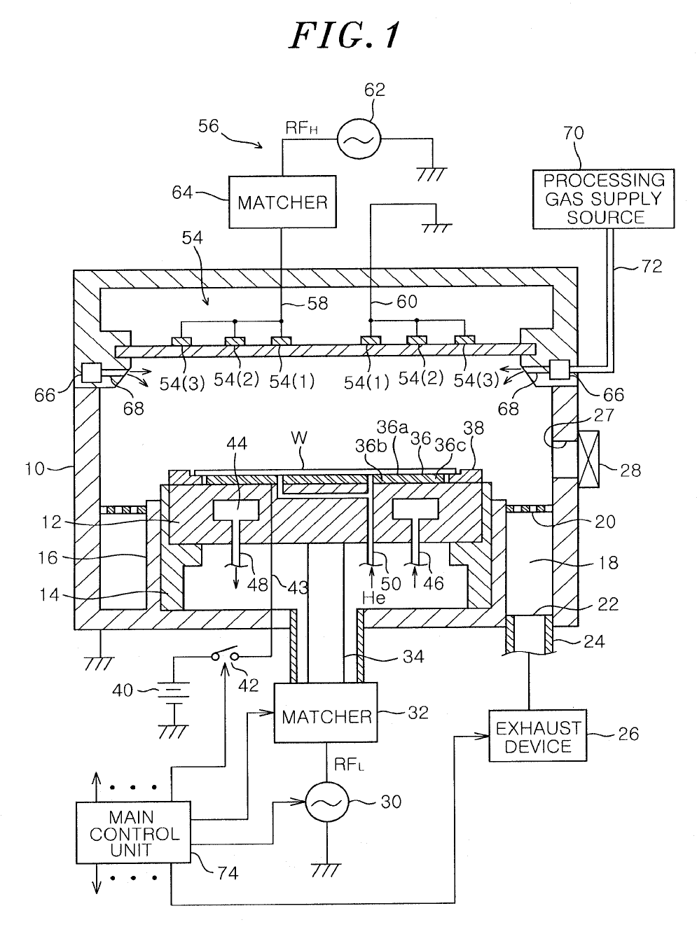

FIG. 1 shows a configuration of an inductively coupled plasma etching apparatus in accordance with an embodiment of the present invention. The inductively coupled plasma etching apparatus is of a type using a planar coil type RF antenna, and includes a cylindrical vacuum chamber (processing chamber) 10 made of a metal, e.g., aluminum, stainless steel or the like. The chamber 10 is frame-grounded.

In the inductively coupled plasma etching apparatus, various units having no involvement in plasma generation will be described first.

At a lower central portion of the chamber 10, a circular plate-shaped susceptor 12 for mounting thereon a target substrate, e.g., a semiconductor wafer W as a substrate supporting table is horizontally arranged. The susceptor 12 also serves as an RF electrode. The susceptor 12, which is made of, e.g., aluminum, is supported by an insulating tubular support 14 uprightly extending from a bottom portion of the chamber 10.

A conductive tubular support part 16 is provided uprightly extending from the bottom portion of the chamber 10 along the periphery of the insulating tubular support 14, and an annular exhaust path 18 is defined between the support part 16 and an inner wall of the chamber 10. Moreover, an annular baffle plate 20 is attached to an entrance or a top portion of the exhaust path 18, and an exhaust port 22 is provided at a bottom portion thereof.

To allow a gas to uniformly flow in the chamber 10 axisymmetrically with regard to the semiconductor wafer W on the susceptor 12, it is preferable to provide a plural number of exhaust ports 22 at a regular interval circumferentially. The exhaust ports 22 are connected to an exhaust device 26 via respective exhaust pipes 24. The exhaust device 26 includes a vacuum pump such as a turbo molecular pump to evacuate a plasma-processing space in the chamber 10 to a predetermined vacuum level. Attached to the sidewall of the chamber 10 is a gate valve 28 for opening and closing a loading/unloading port 27.

An RF power supply 30 for an RF bias is electrically connected to the susceptor 12 via a matcher 32 and a power supply rod 34. The RF power supply 30 outputs a variable RF power RF_{L} of an appropriate frequency (e.g., 13.56 MHz or less) to control the energy for attracting ions toward the semiconductor wafer W. The matcher 32 includes a variable-reactance matching circuit for performing the matching between the impedances of the RF power supply 30 and the load (mainly, susceptor, plasma and chamber), and the matching circuit includes a blocking capacitor for generating a self-bias.

An electrostatic chuck 36 is provided on an upper surface of the susceptor 12 to hold the semiconductor wafer W by an electrostatic attraction force, and a focus ring 38 is provided around the electrostatic chuck 36 to annularly surround the periphery of the semiconductor wafer W. The electrostatic chuck 36 includes an electrode 36a made of a conductive film and a pair of dielectric films 36b and 36c. A high voltage DC power supply 40 is electrically connected to the electrode 36a via a switch 42 by using a coated line 43. By applying a high DC voltage from the DC power supply 40 to the electrode 36a, the semiconductor wafer W can be attracted to and held on the electrostatic chuck 36 by the electrostatic force.

A coolant path 44, which extends in, e.g., a circumferential direction, is provided inside the susceptor 12. A coolant, e.g., a cooling water, of a predetermined temperature is supplied from a chiller unit (not shown) to the coolant path 44 to be circulated through pipelines 46 and 48. By adjusting the temperature of the coolant, it is possible to control a process temperature of the semiconductor wafer W held on the electrostatic chuck 36.

Moreover, a heat transfer gas, e.g., He gas, is supplied from a heat transfer gas supply unit (not shown) to a space between a top surface of the electrostatic chuck 36 and a bottom surface of the semiconductor wafer W through a gas supply line 50. Further, an elevating mechanism (not shown) including lift pins capable of being moved up and down while vertically extending through the susceptor 12, and the like is provided to load and unload the semiconductor wafer W.

Next, various units having involvement in the plasma generation in the inductively coupled plasma etching apparatus will be described.

A ceiling or a ceiling plate of the chamber 10 is separated from the susceptor 12 at a relatively large distance, and a circular dielectric window 52 formed of, e.g., a quartz plate is airtightly provided in the ceiling. As a single unit with the chamber 10, an antenna chamber for accommodating an RF antenna 54 while electronically shielding it from the outside is provided on the dielectric window 52. The RF antenna 54 is used to generate an inductively coupled plasma in the chamber 10.

In the present embodiment, the RF antenna 54 includes a plurality of (, e.g., three in FIG. 1) ring-shaped (i.e., the radius is unchangeable in the circling direction) single-wound coils 54(1) to 54(3) having different radiuses. The coils 54(1) to 54(3) are concentrically horizontally attached on the dielectric window 52 and electrically connected in parallel with an RF power supply unit 56 through a pair of RF power supply lines 58 and 60. Typically, each of the coils 54(1) to 54(3) is concentrically arranged with regard to the chamber 10 and the susceptor 12.

The RF power supply unit 58 includes an RF power supply 62 and a matcher 64 and outputs a variable RF power RF_{H} of an appropriate frequency (e.g., 13.56 MHz or more) for plasma generation by RF discharge. The matcher 64 includes a variable-reactance matching circuit for performing the matching between the impedances of the RF power supply 62 and the load (mainly, RF antenna and plasma).

A processing gas supply unit for supplying a processing gas to the chamber 10 includes an annular manifold or buffer unit 66 provided inside (or outside) the sidewall of the chamber 10 to be located at a place slightly lower than the dielectric window 52; a plurality of sidewall gas injection holes 68 circumferentially formed on the sidewall at a regular interval and opened to the plasma-generation space from the buffer unit 66; and a gas supply line 72 extended from the processing gas supply source 70 to the buffer unit 66. The processing gas supply source 70 includes a mass flow controller and an on-off valve, which are not shown.

A main control unit 74 includes, e.g., a microcomputer and controls the overall operation (sequence) of the plasma etching apparatus and individual operations of various units, e.g., the exhaust device 26, the RF power supplies 30 and 62, the matchers 32 and 64, the switch 42 of the electrostatic chuck, the processing gas supply source 70, the chiller unit (not shown), the heat-transfer gas supply unit (not shown) and the like.

When the inductively coupled plasma etching apparatus performs an etching process, the gate valve 28 is first opened to load a target substrate, i.e., a semiconductor wafer W, into the chamber 10 and mount it onto the electrostatic chuck 36. Then, the gate valve 28 is closed, and an etching gas (typically, a gaseous mixture) is introduced from the processing gas supply source 70, via the buffer unit 66, into the chamber 10 at a preset flow rate and flow rate ratio through the sidewall gas injection holes 68 by using the gas supply line 72. Thereafter, the RF power supply 70 of the RF power supply unit 56 is turned on to output a plasma-generating RF power RF_{H} at a predetermined RF level, so that a current of the RF power RF_{H} is supplied to the respective coils 54(1) to 54(3) of the RF antenna 54 through the RF power supply lines 58 and 60 via the matcher 64. In addition, the RF power supply 30 is turned on to output an ion-attracting control RF power RF_{L} at a predetermined RF level, so that the RF power RF_{L} is supplied to the susceptor 12 through the power supply rod 34 via the matcher 32.

Further, a heat-transfer gas (i.e., He gas) is supplied from the heat-transfer gas supply unit to a contact interface between the electrostatic chuck 36 and the semiconductor wafer W, and the switch is turned on, so that the heat-transfer gas is confined in the contact interface by the electrostatic attraction force of the electrostatic chuck 36.

The etching gas injected through the sidewall gas injection holes 68 is uniformly diffused in the processing space below the dielectric window 52. At this time, magnetic force lines (magnetic flux) generated around the respective coils 54(1) to 54(3) by the current of the RF power RF_{H} flowing through the respective coils 54(1) to 54(3) of the RF antenna 54 travel through dielectric window 52 and across the processing space (plasma generation space) of the chamber 10, to thereby induce an electric field azimuthally in the processing space. Electrons azimuthally accelerated by the induced electric field collide with molecules and/or atoms in the etching gas, to thereby ionize the etching gas and generate a plasma in a doughnut shape.

In the wide processing space, radicals and ions of the plasma generated in the doughnut shape are diffused in all directions, so that the radicals isotropically pour down and the ions are attracted by the DC bias onto a top surface (target surface) of the semiconductor wafer W. Accordingly, plasma active species cause chemical and physical reactions on the target surface of the semiconductor wafer W, thereby etching a target film into a predetermined pattern.

Here, the expression “plasma in a doughnut shape” indicates not only a state where the plasma is generated only at the radially outer portion in the chamber 10 without being generated at the radially inner portion (at the central portion) therein but also a state where the volume or density of the plasma generated at the radially outer portion becomes larger than that at the radially inner portion. Moreover, if the kind of the processing gas, the pressure inside the chamber 10 and/or the like are changed, the plasma may be generated in another shape instead of the doughnut shape.

In the inductive coupled plasma etching apparatus, there has been special studies on the respective coils 54(n) (n=1, 2, 3) of the RF antenna in order to improve the uniformity in the azimuthal direction of the plasma process properties, i.e., etching properties (etching rate, selectivity, etching shape and the like), of the semiconductor wafer W.

FIG. 2 shows a basic structure of the coil 54(n) of the RF antenna 54 in accordance with a first test example of the present embodiment. The coil 54(n) is formed of a ring-shaped coil conductor 82 having a cutout portion 80 in a coil circling direction. The RF power supply lines 58 and from the RF power supply unit 56 are respectively connected to connection points or power supply points RF-In and RF-Out on coil end portions 82a and 82b that are opposite to each other, the cutout portion 80 being arranged therebetween.

The coil 54(n) features the cutout portion 80 having a gap width “g” that is significantly narrow (e.g., 10 mm or less preferably).

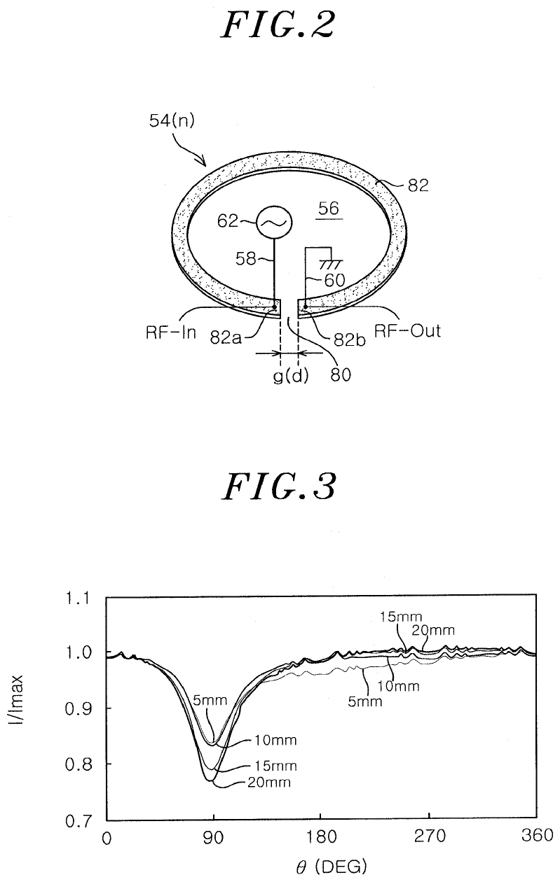

The present inventors verified the correlative relationship between the gap width “g” of the 54(n) and the non-uniformity in the circling direction (azimuthal direction) of a current excited in the chamber 10 through electromagnetic system simulations. Specifically, the gap width “g” of the 54(n) was set to be, e.g., 5, 10, 15 and 20 mm as parameters, and the density I (corresponding to plasma density) of a current generated on a circle having a radius of 120 mm at a portion of a depth of 5 mm in the plasma generated in the doughnut shape in the chamber 10 was calculated. Then, the calculated result was normalized such that a maximum value Iₘₐₓ became 1 to be plotted. Resultantly, the characteristics shown in FIG. 3 were obtained.

In the electromagnetic system simulations, a model was supposed, wherein the inner radius and the outer radius of the coil 54(n) were respectively set to be, e.g., 110 and 130 mm; the thickness of the dielectric window (quartz plate 10) 52 was set to be, e.g., 10 mm; and a plasma having a skin depth of, e.g., 10 mm was generated in the doughnut shape immediately below the dielectric window 52 by the inductive coupling with an ion sheath having a thickness of, e.g., 5 mm interposed therebetween. As the plasma generated in the doughnut shape, a disk-shaped resistance was simulated, where its radius and resistivity were set to be, e.g., 250 mm and 100 Ωcm, respectively. The plasma-generating RF power RF_{H} had has a frequency of about 13.56 MHz. The distance “d” between the RF power supply points RF-In and RF-Out of the coil 54(n) was set identically to the gap width “g”.

In FIG. 3, a location (about 90 degree) where the current density I is decreased corresponds to that of the cutout portion 80. As shown in FIG. 3, when the gap width “g” is 15 mm, about 20% is decreased from the maximum value Iₘₐₓ of the current density I. When the gap width “g” is 20 mm, about 23% is decreased from the maximum value Iₘₐₓ of the current density I. Moreover, it is seen that the current density I becomes more decreased when the gap width “g” is greater than 20 mm. On the other hand, when the width gap “g” is 5 or 10 mm, only about 15% is decreased from the maximum value Iₘₐₓ of the current density I.

Accordingly, in the inductively coupled plasma etching apparatus, the gap width “g” of the cutout portion 80 of the coil 54(n) constituting the RF antenna 54 may be required to be set to be 10 mm or less in order to improve the uniformity in the azimuthal direction of the density of the plasma generated in the doughnut shape in the chamber 10 by changing the structure of the RF antenna 54.

Interestingly, such condition (g≤10 mm) of the gap width “g” of the cutout portion 80 corresponds to the condition (δ≤10 mm) of the skin depth δ of the plasma generated in the doughnut shape by the inductive coupling. The skin depth δ_{c} of a collision system and the skin depth δₚ of a collisionless system are respectively calculated by the following Eqs. 1 and 2.

δ_{c}=(2πₘ/ω)^{1/2}c[(e²nₑ)/(ε₀mₑ)]^{-1/2} Eq. 1

δₚ=c[(e²nₑ)/(ε₀mₑ)]^{-1/2} Eq. 2,

where πₘ, ω, c, e, nₑ, ε₀, and mₑ respectively indicate electron-neutron inertia conversion collision frequency, angular frequency of plasma-generating RF power, speed of light, charge amount of electron, density of electron, dielectric constant of free space, and mass of electron.

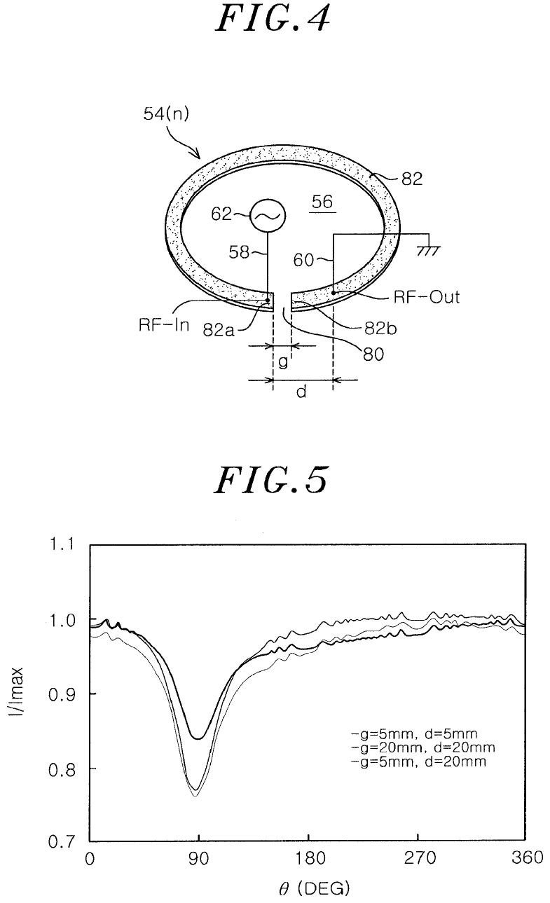

In the coil 54(n) of a second test example of the present embodiment, both of the gap width “g” of the cutout portion 80 and the distance “d” between the RF power supply points RF-In and RF-Out become important factors. In other words, as shown in FIG. 4, the gap width “g” of the cutout portion 80 may be narrow, while the distance “d” between the RF power supply points RF-In and RF-Out may be wide.

In the electromagnetic system simulations, the gap width “g” and the distance “d” was respectively set to be, e.g., 5 and 5 mm, 20 and 20 mm and 5 and 20 mm as parameters, and other conditions were set to be the same as the above. Then, the density I of the plasma generated in the doughnut shape in the chamber 10 was calculated. Resultantly, the plotted characteristics shown in FIG. 5 were obtained. In other words, the case of the gap width “g” of 5 mm and the distance “d” of 20 mm was identical to that of the gap width “g” of 20 mm and the distance “d” of 20 mm, and the current density I was decreased by about 23% at a location corresponding to the cutout portion 80.

Accordingly, in the inductively coupled plasma etching apparatus, both of the gap width “g” of the cutout portion 80 and the distance “d” between the RF power supply points RF-In and RF-Out in the coil 54(n) constituting the RF antenna 54 may be required to be set narrowly (e.g., 10 mm or less) in order to improve the uniformity in the azimuthal direction of the density of the plasma generated in the doughnut shape in the chamber 10 by changing the structure of the RF antenna 54.

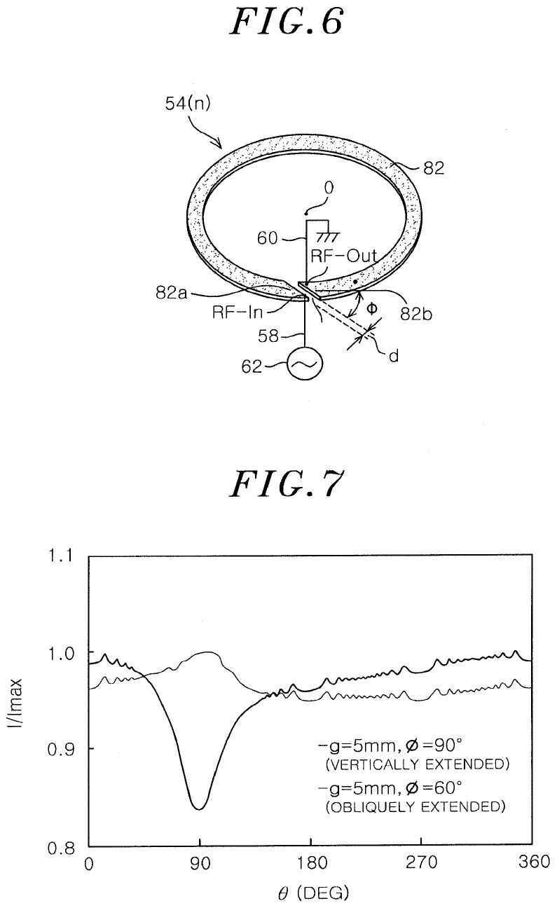

FIG. 6 shows a preferable third test example of the coil 54(n). The test example features a cutout portion 80 of the coil 54(n) that obliquely extends by a predetermined angle φ (e.g., φ=60°) with respect to the coil circling direction. In this case, it is most preferable that the RF power supply points RF-In and RF-Out are located to be overlapped with each other in the coil circling direction, or the center “O” of the circular coil 54(n) and the RF power supply points RF-In and RF-Out are arranged in the same straight line in the coil radial direction.

In case that the coil 54(n) has the ring shape or another (e.g., rectangular) shape and the cutout portion 80 is obliquely provided with respect to the coil circling direction, it is preferable that the RF power supply points RF-In and RF-Out are located such that there is no gap in the coil circling direction between the RF power supply point RF-In at which one RF power supply line 58 is connected to one coil end portion 82a and the RF power supply point RF-Out at which the other RF power supply line 60 is connected to the other coil end portion 82b, and it is most preferable that the RF power supply points RF-In and RF-Out are located to be overlapped with each other in the coil circling direction.

Moreover, in the electromagnetic system simulations, the gap width “g” and the predetermined angle φ was respectively set to be, e.g., 5 mm and 90° and 5 mm and 60° as parameters, and other conditions were set to be the same as the above. Then, the distribution in the azimuthal direction of the density I of a current excited in the plasma in the doughnut shape was calculated. Resultantly, the plotted characteristics shown in FIG. 7 were obtained.

Here, the case of the gap width “g” of 5 mm and the predetermined angle φ of 90° corresponds to the test example shown in FIG. 6, and the case of the gap width “g” of 5 mm and the predetermined angle φ of 60° corresponds to the test example shown in FIG. 2. In other words, in the test example shown in FIG. 2, the cutout portion 80 of the coil 54(n) is linearly extended perpendicular to the coil circling direction and, thus, the predetermined angle φ is defined as 90°.

As shown in FIG. 7, in the test example shown in FIG. 6 where the cutout portion 80 of the coil 54(n) is obliquely provided with respect to the coil circling direction, the current density I is increased at a location corresponding to the cutout portion 80 instead of being decreased. Further, the deviation in the azimuthal direction of the current density I is generally improved to about 4%, which is very small.

In the test example shown in FIG. 6, the reason that the current density I is increased at the location corresponding to the cutout portion 80 as compared with other cases is that the RF power supply points RF-In and RF-Out are located to cross over each other by 5 mm and, thus, a coil current immediately after flowing into the RF power supply point RF-In and another coil current immediately before flowing from the RF power supply point RF-Out are overlapped with each other in the same direction. Accordingly, in case that the RF power supply points RF-In and RF-Out are located to cross over each other, it is expected that the deviation (non-uniformity) of the current density I in the azimuthal direction is decreased more and more.

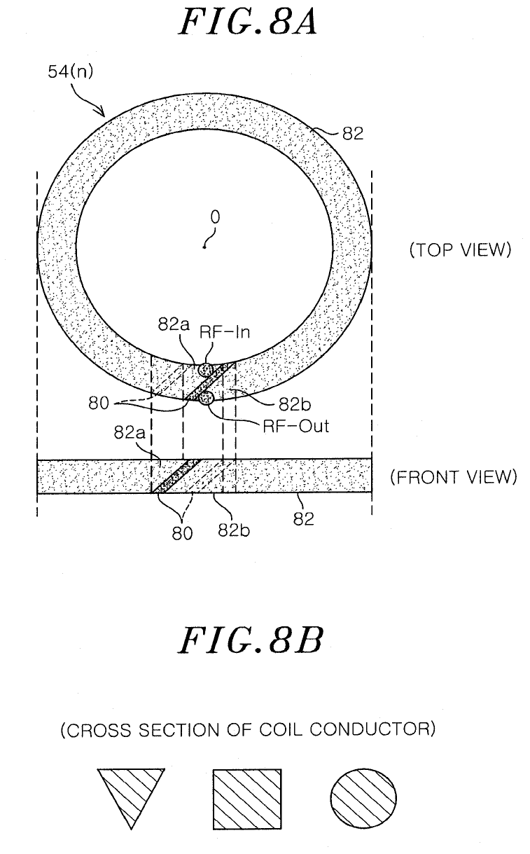

A fourth test example shown in FIG. 8A features a cutout portion 80 of the coil 54(n) that faces from an inner peripheral surface of the coil conductor 82 to an outer peripheral surface thereof and is obliquely extended from a top surface of the coil conductor 82 to a bottom surface thereof. With such configuration, the location of the cutout portion 80 is difficult to be seen from the plasma side and, thus, the pseudo-continuity of the coil conductor 82 of the coil 54(n) in the circling direction is further improved.

The coil conductor 82 of the coil 54(n) may have any sectional shape, e.g., a triangular shape, a quadrangular shape or a circular shape as shown in FIG. 8B.

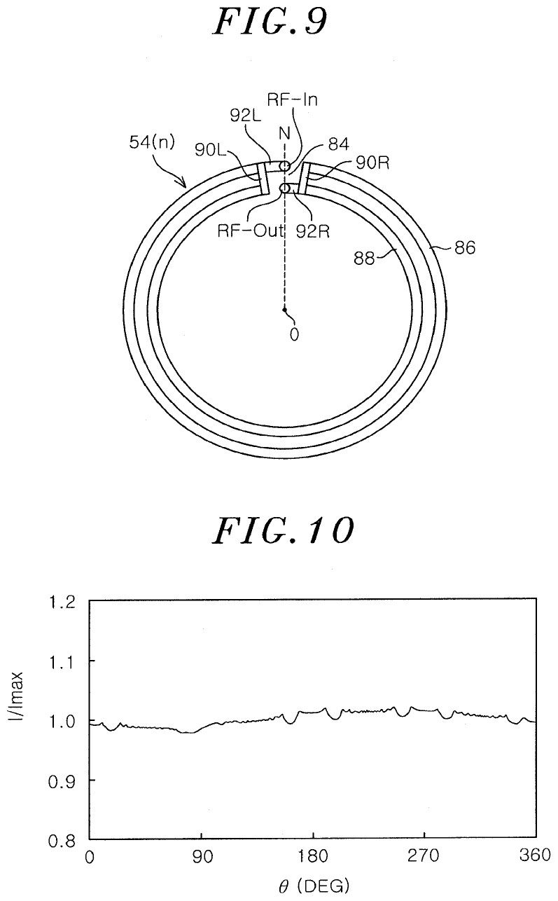

FIG. 9 shows an effective fifth test example for removing or suppressing singularities caused by a cutout portion 84 of the coil 54(n). In the fifth test example, the coil 54(n) includes an outer and an inner coil conductor 86 and 88 extended in parallel to be adjacent with each other, the cutout portion 84 being provided at the same location in the coil circling direction; a first connection conductor 90L commonly connected to one coil end portions (i.e., left portions in FIG. 9) of the coil conductors 86 and 88 adjacent to the cutout portion 84; a second connection conductor 90R commonly connected to the other coil end portions (i.e., right portions in FIG. 9) of the coil conductors 86 and 88 adjacent to the cutout portion 84; a third connection conductor 92L extended from the first connection conductor 90L into the gap of the cutout portion 84 and connected to one RF power supply line 58 from the RF power supply unit 56 (referring to FIG. 1); and a fourth connection conductor 92R extended from the second connection conductor 90R into the gap of the cutout portion 84 and connected to the other RF power supply line 60 from the RF power supply unit 56 (referring to FIG. 1).

For example, the inner coil conductor 88 has an inner radius of about 108 mm and an outer radius of about 113 mm, and the outer coil conductor 86 has an inner radius of about 118 mm and an outer radius of about 123 mm. The coil conductors 86 and 88 are concentrically arranged at the interval of about 10 mm in the radial direction.

Here, it is most preferable that the RF power supply point RF-In where the RF power supply line 58 is connected to the third connection conductor 92L and the RF power supply point RF-Out where the RF power supply line 60 is connected to the fourth connection conductor 92R are located to be overlapped with each other in the coil circling direction, or the center “O” of the circular coil 54(n) and the RF power supply points RF-In and RF-Out are arranged in a same straight line N in the coil radial direction

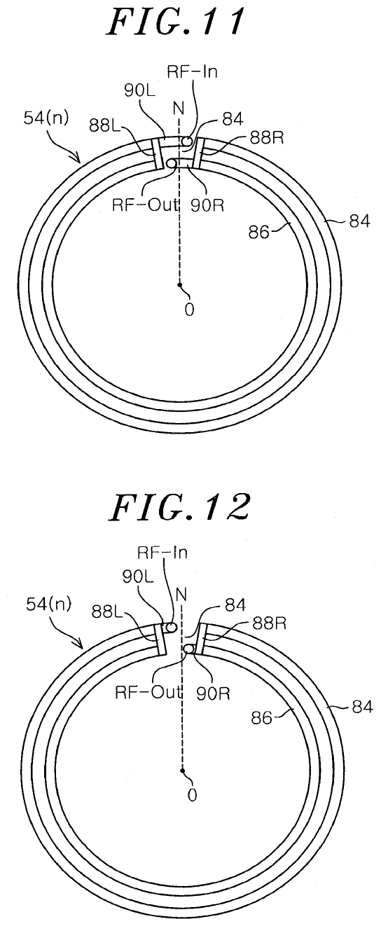

In the electromagnetic system simulations, with the same conditions as the above for the fifth test example, the distribution in the azimuthal direction of the density I of a current excited in the plasma in the doughnut shape was calculated. Resultantly, the plotted characteristics shown in FIG. 10 were obtained. As shown in FIG. 10, the deviation in the azimuthal direction of the current density I is improved to about 2% or less, which is very small.

In a modification of the fifth test example, as shown in FIG. 11, the RF power supply points RF-In and RF-Out may be located to cross over each other in the coil circling direction. In this case, since a coil current immediately after flowing into the RF power supply point RF-In and another coil current immediately before flowing from the RF power supply point RF-Out are overlapped with each other in the same direction, the current density I tends to be slightly increased at the location corresponding to the cutout portion 84 as compared with other cases.

In another modification of the fifth test example, as shown in FIG. 12, the RF power supply points RF-In and RF-Out may be located spaced apart from each other with a gap interposed therebetween in the coil circling direction. In this case, the current density I tends to be slightly decreased at the location corresponding to the cutout portion 84 as compared with other cases.

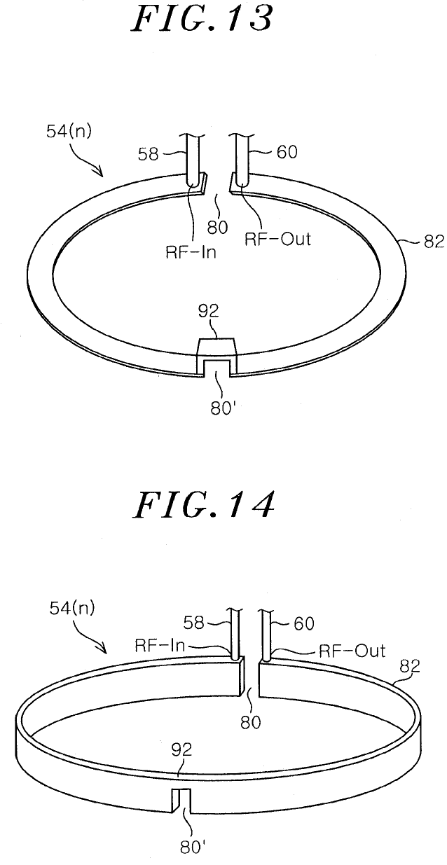

FIGS. 13 and 14 respectively show a sixth test example and its modification where a plurality of (e.g., two in FIGS. 13 and 14) cutout portions 80 and 80′ are provided at a regular interval in the circling direction in the coil 54(n). In this case, one cutout portion 80 is an original cutout portion for being connected to the RF power supply lines 58 and 60, and the other cutout portion(s) 80′ is a dummy cutout portion(s). At each of the cutout portions 80′, a bridge-type connection conductor 92 is provided to connect a pair of coil end portions that are opposite to each other via a corresponding cutout portion 80′.

Typically, the inductively coupled plasma processing apparatus is designed such that a plasma is generated radially non-uniformly in the doughnut shape immediately below the RF antenna (coil) and diffused uniformly on the susceptor or the semiconductor wafer. Even in the circling (azimuthal) direction, the plasma generated non-uniformly in the doughnut shape becomes diffused and thus smoothed immediately on the semiconductor wafer. Since, however, the smoothing in the circling direction needs longer distance (corresponding to the circumference) than that in the radial direction, it becomes difficult to smooth the plasma in the circling direction.

In this regard, if a plurality of discontinuous points (cutout portions) are provided at a regular interval in the circling direction in the coil 54(n) as in the sixth text example, the diffusion distance required to smooth the plasma density in the circling direction becomes shortened. For example, if N (N is a natural number and equal to or greater than 2) discontinuous points (cutout portions) are provided, the diffusion distance required to smooth the plasma density becomes 1/N of the circumference and it becomes easy to smooth the plasma density.

In the modification of the sixth test example, as shown in FIG. 14, a coil conductor 82 of the coil 54(n) may be of a vertical type, and the cutout portions 80 and 80′ may be extended in a vertical direction.

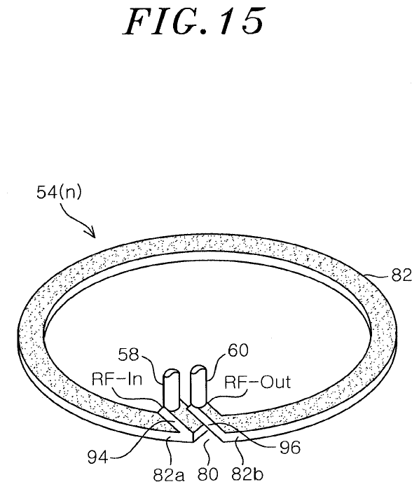

A seventh test example shown in FIG. 15 features a configuration of the coil 54(n) where a pair of connection conductors 94 and 96 are respectively obliquely extended in parallel at a predetermined angle (preferably, from 45 to 70°) with regard to the coil circling direction from upper sides of the coil end portions 82a and 82b that are opposite to each other via a cutout portion 80 of the coil conductor of the coil 54(n) (in the opposite direction to the dielectric window 52), and the RF power supply lines 58 and 60 are respectively connected to front end portions of the connection conductors 94 and 96. Preferably, the cutout portion 80 has a gap width of, e.g., 10 mm or less.

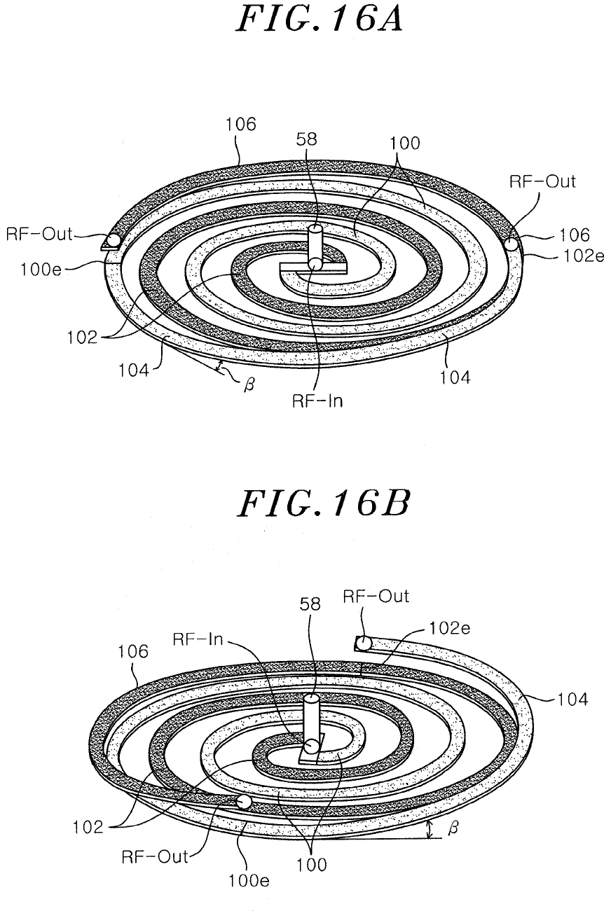

FIGS. 16A and 16B are perspective views showing an eighth test example in case that the RF antenna 54 is formed of a vortex-shaped coil, seen from different angles (directions).

In the present test example, the RF antenna 54 includes a first and a second main coil conductor 100 and 102 vortically extended on a planar surface (e.g., the dielectric window 52) in a phase difference of 180°; and a first and a second sub coil conductor 104 and 106 respectively vortically (i.e., counter-vortically in FIGS. 16A and 16B) extended with regard to the planar surface from peripheral coil end portions 100e and 102e of the first and the second main coil conductor 100 and 102 in a phase difference of 180° upwardly at a predetermined inclined angle β (e.g., 1.5 to 2.5°). One RF power supply line 58 from the RF power supply unit 56 (referring to FIG. 1) is commonly connected to central coil end portions of the first and the second main coil conductor 100 and 102. Similarly, the other RF power supply line 60 from the RF power supply unit 56 (referring to FIG. 1) is commonly connected to upper coil end portions 104u and 106u of the first and the second sub coil conductor 104 and 106.

In general, in the vortex-shaped coil, the RF power supply points RF-In and RF-Out are respectively located at a central end portion and an outer peripheral end portion of the coil separately from each other. Further, the coil end portion 100e and 102e suddenly terminate when they are seen from the plasma side. Accordingly, in the present test example, by connecting the spirally extended sub coil conductors 104 and 106 gradually separated from the plasma side to the coil end portions 100e and 102e as described above, it is possible to improve the uniformity of the density distribution of the plasma around the outer periphery of the coil in the circling direction.

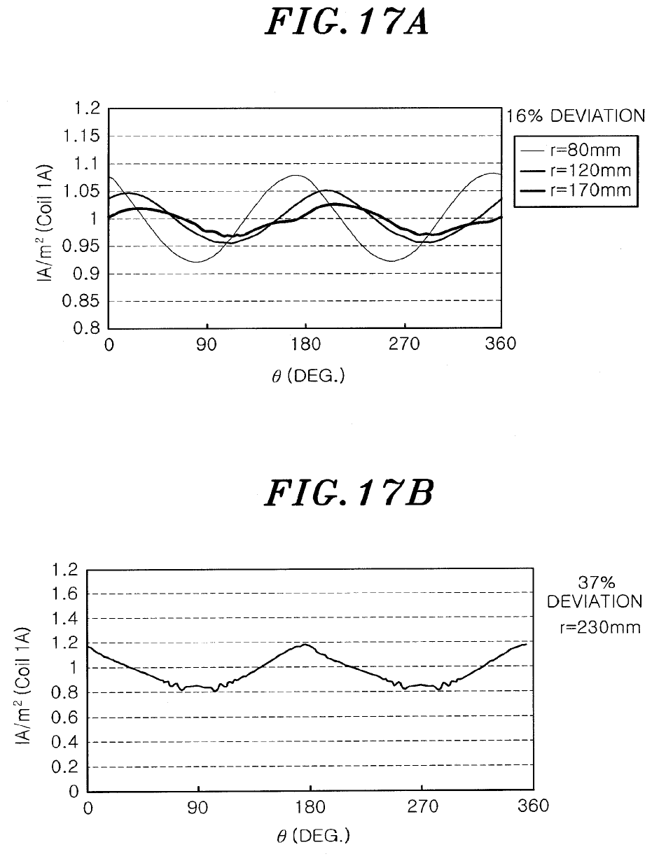

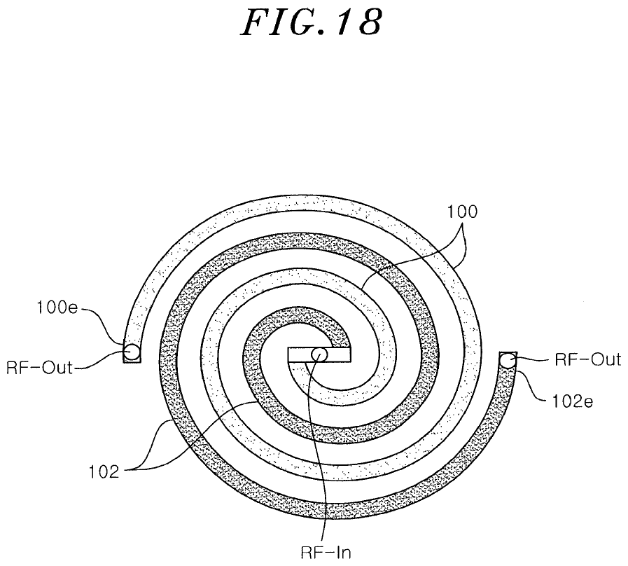

Similarly, the electromagnetic system simulations were performed for the eighth test example shown in FIGS. 16A and 16B to calculate the density I (corresponding to plasma density) of a current generated on each of circles having radiuses of, e.g., 8, 120, 170 and 230 mm. Resultantly, the plotted characteristics shown in FIGS. 17A and 17B were obtained. Further, in the electromagnetic system simulations, the RF antenna 54 had the outer radius of, e.g., 230 mm.

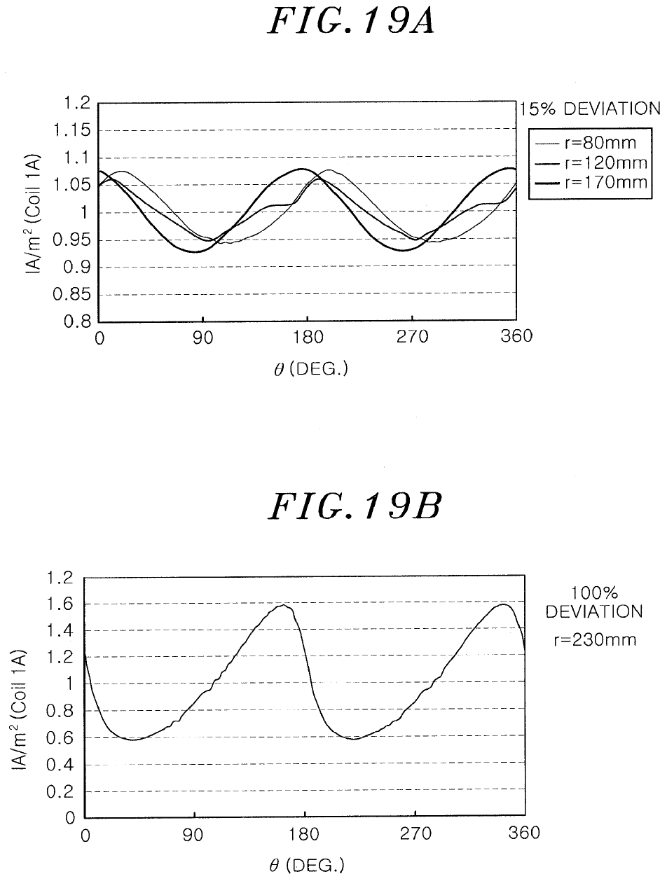

In the meantime, the electromagnetic system simulations were performed for a comparison example shown in FIG. 18, where the sub coil conductors 104 and 106 were not connected to the coil end portions 100e and 102e of the first and the second main coil conductor 100 and 102, and the RF power supply points RF-Out was respectively provided at the coil end portions 100e and 102e, in order to calculate the density I (corresponding to plasma density) of a current generated on each of circles having radiuses of, e.g., 8, 120, 170 and 230 mm. Resultantly, the plotted characteristics shown in FIGS. 19A and 19B were obtained.

The deviations in the circles having the radiuses of 8, 120 and 170 mm in the eighth test example were similar to those in the comparison example (referring to FIGS. 17A and 19A). On the other hand, the deviation in the circle having the radius of 230 mm in the eighth test example was significantly different from that in the comparison example. The deviation was decreased by 37% in the eighth test example when the deviation in the comparison example was determined as 100%.

Moreover, although the RF antenna 54 includes the pair of vortex-shaped main coil conductors 100 and 102 and the pair of vortex-shaped sub coil conductors 104 and 106 in the eighth test example shown in FIGS. 17A and 17B, the RF antenna 54 may include the single vortex-shaped coil conductor 100 and the single vortex-shaped sub coil conductor 104.

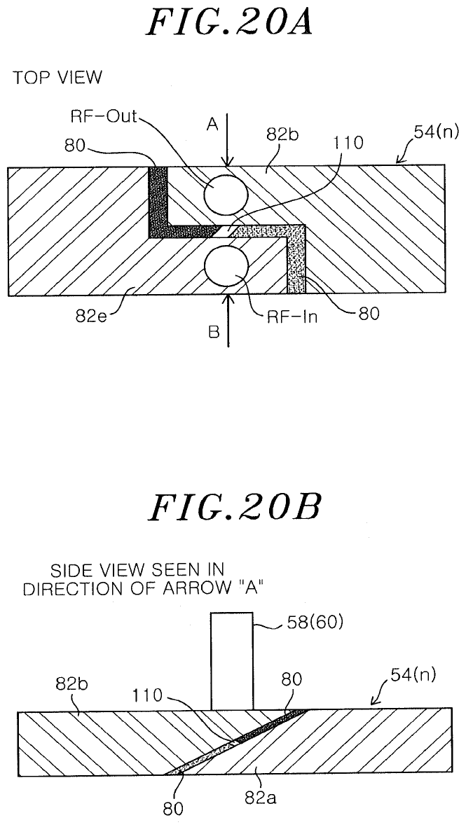

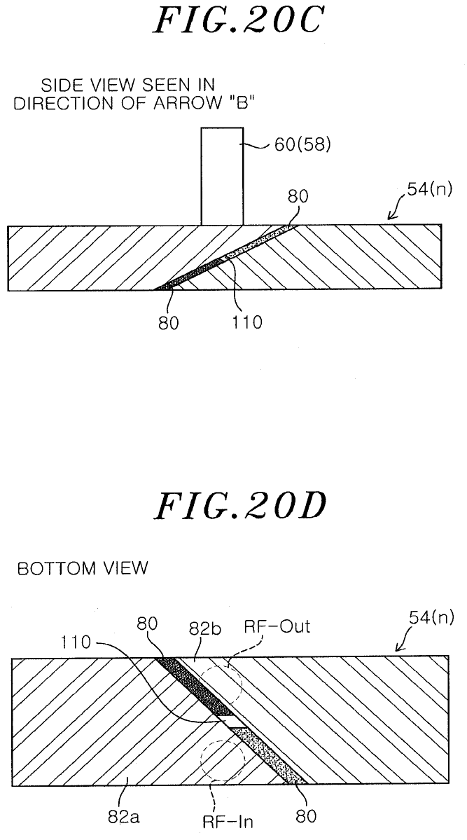

FIGS. 20A to 20D show a ninth test example for the coil 54(n) as a developed example of the first to the fourth test example shown in FIGS. 2 to 8A. A cutout portion 85b can be provided only at one location 110 of a central portion of the coil 54(n) even in any of the directions shown in FIGS. 20A to 20D. With such configuration, the location of the cutout portion is hardly seen from the plasma side, and, thus, the pseudo-continuity of the coil conductor 82 of the coil 54(n) in the circling direction is further improved.

In the aforementioned embodiment of the present invention, the configuration of the inductively coupled plasma etching apparatus is merely an example. Various modifications of the units of the plasma-generation mechanism and units having no direct involvement in the plasma generation may be made.

For example, as another type for supplying an RF power to the RF antenna 54, a capacitor may be connected in at least one of the RF power lines or between at least one (especially, the return power supply line 60) of the RF power lines and a conductive ground member electrically grounded.

Moreover, the basic shape of the RF antenna may be a domical shape instead of the planar shape. Further, in case that the RF antenna includes one or more concentric coils having a same radius, the RF antenna may be installed at a portion other than the ceiling portion of the chamber. For example, a helical RF antenna may be installed outside a sidewall of the chamber.

In case that the RF antenna 54 includes a plurality of single-wound coils 54(1) to 54(3) having different radiuses, individual RF power supply units 56(n) may respectively be connected to the single-wound coils 54(n). Alternatively, multi-wound coils may be used instead of the respective single-wound coils. In the case of, e.g., a rectangular target substrate to be processed, the chamber and the RF antenna may conformingly have a rectangular shape.

Moreover, a processing gas may be supplied through the ceiling of the chamber 10 from the processing gas supply unit, and no DC bias controlling RF power RF_{L} may be supplied to the susceptor 12.

In the above embodiments, the inductively coupled plasma processing apparatus or the plasma processing method therefor is not limited to the technical field of the plasma etching, but is applicable to other plasma processes such as a plasma CVD process, a plasma oxidizing process, a plasma nitriding process and the like. In the embodiments, the target substrate to be processed is not limited to the semiconductor wafer. For example, the target substrate may be one of various kinds of substrates, which can be used in a flat panel display (FPD), a photomask, a CD substrate, a print substrate or the like.

In accordance with the inductively coupled plasma processing apparatus of the present invention, it is possible to improve the uniformity in the azimuthal direction of plasma density distribution by allowing locations on a current loop of an RF input-output terminal of its RF antenna not to be seen while substantially maintaining the length of coils of the RF antenna.

While the invention has been shown and described with respect to the embodiments, it will be understood by those skilled in the art that various changes and modifications may be made without departing from the scope of the invention as defined in the following claims.

What is claimed is:

1. A plasma processing apparatus comprising:
a processing chamber, at least a part of which is formed of a dielectric window;
a substrate supporting unit, provided in the processing chamber, for mounting thereon a target substrate to be processed;
a processing gas supply unit for supplying a desired processing gas to the processing chamber to perform a desired plasma process on the target substrate;
an RF antenna, provided on the dielectric window, for generating a plasma from the processing gas by an inductive coupling in the processing chamber; and
an RF power supply unit for supplying an RF power to the RF antenna, the RF power having an appropriate frequency for RF discharge of the processing gas,
wherein the RF antenna includes: a main coil conductor vortically extended with regard to a planar surface; and a sub coil conductor vortically extended with regard to the planar surface from a peripheral coil end portion of the main coil conductor upwardly at a predetermined inclined angle,
a first RF power line from the RF power supply unit is connected to a central coil end portion of the main coil conductor, and
a second RF power line from the RF power supply unit is connected to an upper coil end portion of the sub coil conductor.

2. The apparatus of claim 1, wherein the main coil conductor of the RF antenna includes a first and a second main coil conductor respectively vortically extended with regard to the planar surface at a phase difference of about 180°,
the sub coil conductor of the RF antenna includes a first and a second sub coil conductor respectively vortically extended with regard to the planar surface from peripheral coil end portions of the first and the second main coil conductor upwardly at a predetermined inclined angle at a phase difference of about 180°,
the first RF power line is commonly connected to central coil end portions of the first and the second main coil conductor, and
the second RF power line is commonly connected to upper coil end portions of the first and the second sub coil conductor.

3. The apparatus of claim 1, wherein a capacitor is provided in at least one of the first and the second RF power line.

4. The apparatus of claim 1, further comprising:
a ground member electrically grounded; and
a capacitor connected between the ground member and at least one of the first and the second RF power line.

5. The apparatus of claim 1, wherein the predetermined inclined angle is in a range of 1.5° to 2.5°.
